(19) United States
(12) Patent Application Publication
(10) Pub. No.: US 2011/0134953 A1
(43) Pub. Date: Jun. 9, 2011

(54) WAVEGUIDE LASER

(75) Inventors: Ulrich Weichmann, Aachen (DE); Jaione Bengoechea Apezteguia, Arraioz (ES); Uwe Mackens, Aachen (DE)

(73) Assignee: KONINKLIJKE PHILIPS ELECTRONICS N.V., EINDHOVEN (NL)

(21) Appl. No.: 13/058,729

(22) PCT Filed: Aug. 6, 2009
(86) PCT No.: PCT/IB2009/053449

§ 371 Date: Feb. 11, 2011

(30) Foreign Application Priority Data
Aug. 15, 2008 (EP) 08105052.8

(51) Int. Cl. H01S 5/10

(52) U.S. Cl. 372/49.01

(57) ABSTRACT

It is an object of the invention to provide a simple setup of a waveguide laser which allows to control the emission of specific laser wavelengths in a laser material having laser transitions of similar wavelengths. For this purpose a core (4) forming a gain medium is provided with a cladding (6) which introduces losses to an undesired laser transition but is transparent to the light of a desired laser transition. A second cladding (8) is provided for guiding the laser radiation. Pr: ZBLAN with a Tb: doped cladding may be used. Instead of the absorbing cladding (6) a photonic crystal (20) may be used. The laser is end-pumped by a laser diode (14).

### FIELD OF THE INVENTION

The invention generally relates to the field of laser technology. More specifically, the invention concerns a waveguide laser set up for selection of a specific laser wavelength.

### BACKGROUND OF THE INVENTION

Lasers based on the Pr-ion have recently attracted a lot of interest. Pr:ZBLAN fibre lasers, for example, have been successfully set up both with up-conversion as well as blue diode pumping to generate laser radiation in the red (˜635 nm), cyan (˜491 nm) and green (˜521 nm) wavelength region. The laser setup is relatively simple; laser radiation is coupled into the Pr-doped core of the fibre via one facet and an opposite facet for outcoupling the laser radiation. Both facets are appropriately coated with dielectric layers or suitable mirrors are attached to the facets: The entrance facet should allow for a high transmission of the pump radiation (inter alia blue light at around 443 nm or around 479 nm, or infrared for up-conversion pumping between 800 and 900 nm) and a high reflection at the wavelength of the desired laser radiation. The opposite facet should provide some transmittance (typically 1 . . . 30%) for the laser wavelength so that it acts as an outcoupler. Additionally, the efficiency of the laser can be improved by reflecting the pump radiation that was not absorbed in a single pass through the fiber back via the second facet coating.

However, as has been published recently in “GaN-diode pumped Pr³⁺:ZBLAN fiber-lasers for the visible wavelength range”, U. Weichmann, J. Baier, J. Bengoechea and H. Moench, paper presented at the CLEO/Europe conference Munich 2007, CJ-347, these types of coating were quite successfully applied for red and cyan lasers, but until now it was not possible to obtain lasing in the green without taking additional measures. This involved the setup of an additional external output coupler to increase the feedback for the green laser. The underlying problem was that the wavelengths of the green and cyan transitions are too close to each other. With typical dielectric multilayer coatings it was not possible to obtain a design with a high enough transmission for the cyan and still a high Q-factor for the green laser.

### SUMMARY OF THE INVENTION

It is therefore an object of the invention to provide a simple setup which allows to control the emission of specific laser wavelengths in a laser material having laser transitions of similar wavelengths. This object is achieved by the subject matter of claim 1. Advantageous refinements of the invention are specified in the dependent claims.

The general idea is to provide a core forming a gain medium with a cladding which introduces losses to an undesired laser transition but is transparent to the light of a desired laser transition.

Accordingly, a waveguide-laser is provided comprising a waveguide with an elongated core and at least one cladding which at least partially surrounds the core. The core comprises a host material doped with a dopant. The dopant provides at least two laser transitions at a first and a second wavelength. The host material is transparent at least at the first wavelength. To suppress or damp laser emission at the second wavelength, the cladding is transparent to the laser light of the first wavelength and the pump light and absorbs or outcouples laser light of the second wavelength.

Preferably, the absorption coefficient of the host material at the first wavelength is less than α=0.005 cm⁻¹ to provide good transparency. If an absorbing dopant is used in the cladding to introduce losses to the second wavelength, the absorption coefficient at this wavelength within the cladding preferably is at least α=0.01 cm⁻¹.

Excitation of the core forming the gain medium may be achieved both by up-conversion and linear conversion.

This setup is particular useful if the wavelengths of the laser transitions are close to each other. In particular, the invention is advantageous if the difference of the wavelengths of the laser transitions is less than 75 nm, preferably less than 50 nm.

Moreover, the invention allows to select a laser transition which is weaker than a further adjacent laser transition. Thus, according to an advantageous refinement, a dopant with laser transitions at the first and second wavelengths is, the laser transition at the first wavelength being weaker than the laser transition at the second wavelength.

The invention is particularly suited to provide a green-emitting praseodymium-doped waveguide laser to avoid the problems discussed in the background section.

According to a preferred embodiment of the invention, it is therefore suggested to surround the active, Pr-doped medium or host material in a waveguide- or fibre-laser with a cladding that introduces losses for the cyan radiation, while the pump and green laser radiation is transmitted without losses or at least without considerable losses. In this way losses for the cyan wavelength are introduced into the laser cavity in a simple way while the laser gain can still be taken over by the green transition. There is no need for complicated designs of the dielectric coatings or mirrors at the fibre or waveguide facets.

Accordingly, a waveguide-laser is proposed comprising a waveguide with an elongated core and at least one cladding at least partially surrounding the core.

The core comprises a host material doped with Praseodymium-ions. The host material is selected to be transparent at a wavelength of around 521 nm. preferably 521±5 nm. The cladding absorbs or outcouples light having a wavelength of about 490±5 nm.

The invention may in principle also be applied to select one of the laser transitions at 635 nm (red light) and 603 nm (orange light) of a Pr³⁺-doped core. The wavelengths of the laser transitions depend on the host material. The values as given above are typical for Pr:ZBLAN. In case of Pr:YLF, the wavelengths of the laser transitions are typically located at 523 nm, 607 nm and 640 nm. Further, in case of Pr:KY₃F₁₀, the transitions are typically found at 523 nm, 609 nm and 645 nm.

Preferably, the pump light source is coupled to one of the end faces of the waveguide. However, as the cladding is transparent to the pump light, it is also possible to introduce the pump light laterally into the waveguide core.

In particular, it is advantageous if the cladding is transparent to the light of a pump light source and guides the light of pump source. This enables double-clad pumping, wherein the pump light is at least partly coupled into the end-face of the cladding instead of coupling the pump light into the core. In comparison to a coupling into the core, coupling the pumping light into the cladding relaxes the requirements to align the pump light source to the waveguide.

It is further advantageous to employ a second cladding at least partially surrounding the first cladding. The second cladding facilitates guiding of the laser light and/or the pump light. This embodiment is particularly suitable if the desired laser light is guided within the first cladding that absorbs or outcouples the laser light of the second wavelength.

To absorb the laser light of the second wavelength, the cladding may be provided with a suitable dopant which absorbs laser light of this wavelength and which is transparent or at least substantially transparent at the first wavelength. In the preferred case of a Pr³⁺-doped core, the laser light of 490 nm can be absorbed using a cladding with a host material doped with Tb-ions (Tb³⁺-ions) in the cladding. Other dopants absorbing the undesired laser light may be used alternatively or additionally. In particular, rare earth ions other than Tb³⁺ in the case of a Tb³⁺-doped core may be employed as absorbing dopant in the cladding, as well.

The concentration of the dopant (such as in particular Pr³⁺-ions) in the core, is preferably chosen to lie within a range between 100 and 10000 ppm. For the dopant in the cladding (such as in particular Tb³⁺-ions) for the absorption of the undesired laser light of the second wavelength the concentration is preferably chosen to lie within a range between 100 and 50000 ppm.

Another possibility is a cladding with a photonic structuring, in particular in the form of a hologram so that light of the first wavelength (preferably light of 521 nm in the case of a Pr³⁺-doped core) is guided within the cladding, and light of the second wavelength (preferably light of a wavelength of 490 nm in the case of a Pr³⁺-doped core) is coupled out.

A preferred material both of the core and the cladding is ZBLAN-glass. ZBLAN glass generally contains fluorides of zirconium, barium, lanthanum, aluminum and sodium. A possible composition range is 45 to 60 mole percent ZrF₄, 20 to 45 mole percent BaF, 2 to 8 mole percent LaF₃, 1 to 8 mole percent AlF₃, and 15 to 25 mole percent alkaline fluoride such as NaF. ZBLAN glass is generally characterized by a low phonon energy and high transparency in the visible range. Due to the low phonon energy, non-radiative recombination of the exited states in the gain medium of the core is suppressed.

Of course, other host-materials having a low characteristic phonon energy may be employed as well. Advantageously, the phonon energy of the host material of the core is below 750 cm⁻¹.

It is further preferable to use a host material with a high band gap, particular preferable a band gap E_{g} exceeding 6.5 eV. Materials having both a high band gap and a low phonon energy are fluoride crystals (YLF, LiLuF₄, KY₃F₁₀, CaF₂, . . . ), ceramic or amorphous materials, e.g. telluride glasses, ceramic or amorphous layers of the fluoride materials mentioned before.

Generally, it is advantageous to use the same material for the host of the core and the cladding. For example, a ZBLAN-core doped with Pr³⁺-ions may be surrounded by a ZBLAN cladding doped with Tb³⁺-ions. Using the same or at least substantially the same material for both the cladding and the core is advantageous to avoid thermal stress and facilitates the production of the waveguide.

Further, the core and the cladding may differ in their refractive index and/or dispersion. Even if the same host material is used for the core and the cladding, the refractive index can be varied due to the different doping. The core may have a higher refractive index than the cladding at the first wavelength so that the desired laser wavelength is guided. However, the waveguide laser according to the invention also works if the refractive indices are equal or similar. In this case the desired laser light is guided both within the core and cladding.

Moreover, the dispersion of the core and/or cladding material may be adjusted or chosen so that the refractive index at the pump light wavelength or within the pump light wavelength range is similar within core and cladding. Preferably, the difference may be less than Δn=0.05. This facilitates transition of pump light from the cladding into the core.

Furthermore, the sign of the refractive index difference between core and cladding may even be reversed within the wavelength range between the first and second wavelength. In this case, the desired laser light of the first wavelength is guided within the core and the undesired laser light of the second wavelength is outcoupled as there is no total reflection at the interface for the second wavelength.

Thus, according to a refinement of the invention, the core and cladding materials are chosen so that the refractive index of the core at the first wavelength is higher than the refractive index of the cladding and is lower than the refractive index of the cladding at the second wavelength. A switch in the sign of the refractive index between the first wavelength and the second laser wavelength can be introduced by suitable dopants in the core or the cladding which absorb near one of these wavelengths or between the wavelengths so that anomalous dispersion is introduced in the respective material.

One preferred design of a waveguide laser is a fiber laser. According to this embodiment, the core is a fiber which is circumferentially surrounded by the cladding material.

Another preferred design is a planar waveguide laser. In this case, the waveguide is a planar waveguide arranged on a substrate as a carrier.

The invention is very suitable to provide laser light sources for display devices, in particular laser projection display devices. Using a Pr³⁺-doped core, the green color component for a display, in particular an image- or video display device can be provided with a considerably simplified design compared to known green emitting lasers. For example, the invention may be employed in a projector based on the laser display technology (LDT) or grating light valve technology (GLV).

### BRIEF DESCRIPTION OF THE DRAWINGS

FIG. 1 shows a cross sectional view of a double-clad fibre, suitable for a green Pr:ZBLAN laser.

FIG. 2 shows a schematic drawing of a planar waveguide laser with a layer structure.

FIG. 3 shows a variant of the embodiment depicted in FIG. 2, the variant employing a lens to focus the pump light onto the waveguide.

FIG. 4 shows a variant of the embodiment of FIG. 2 with a photonic structuring of the cladding.

FIG. 5 shows a diagram of the course of the refractive indices for three wavelengths in radial direction through the waveguide.

FIG. 6 shows a laser image projector.

### DETAILED DESCRIPTION OF EMBODIMENTS

According to the preferred embodiment of the invention it is suggested to surround an active, Pr-doped medium in a waveguide- or fibre-laser with a cladding that is doped in such a way, that losses for the cyan radiation are introduced, while the pump and green laser radiation is transmitted without losses. In this way losses for the cyan wavelength are introduced into the laser cavity in a simple way while the laser gain can still be taken over by the green transition. There is no need for complicated designs of the dielectric coatings or mirrors at the fibre or waveguide facets. Furthermore, the proposed use of this cladding allows for so-called double-clad pumping, where the pump radiation is coupled into the much larger diameter of the cladding, therefore the tolerances of the laser setup are drastically reduced.

In the following some preferred refinements of the proposed invention will be described with respect to the accompanying figures. It should be mentioned that the invention is not limited to blue diode pumping of the Pr-doped material. The invention can also be applied to up-conversion with infrared radiation via the well-known avalanche process in Pr:Yb-doped materials. Also even though the examples described here are on Pr-doped ZBLAN-glass formed to waveguides or fibres, other suitable host materials, characterized by low phonon energies (Eₚₕₒₙₒₙ<750 cm⁻¹) and high band gaps (E_{g}>6.5 eV), like fluoride crystals (YLF, LiLuF₄, KY₃F₁₀, CaF₂, . . . ), ceramic or amorphous materials (e.g. telluride glasses, ceramic or amorphous layers of the fluoride materials mentioned before, . . . ) are suitable.

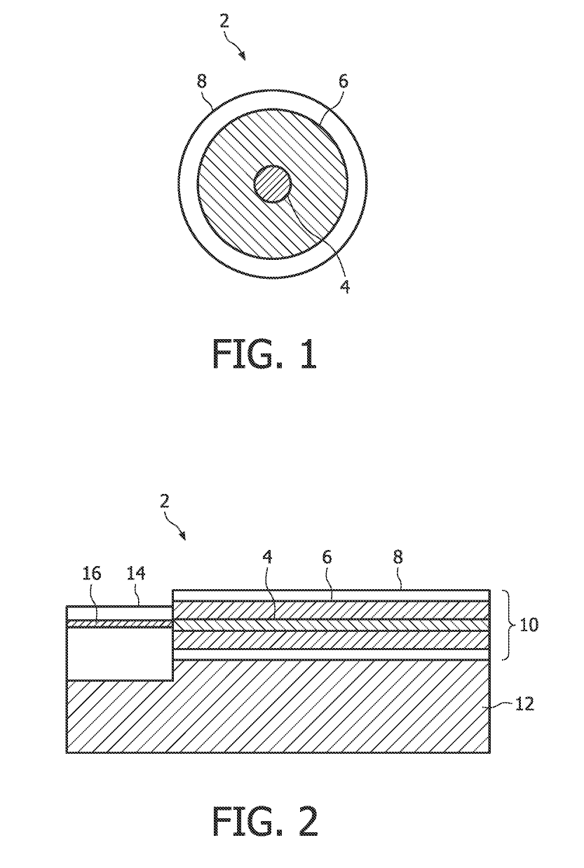

A first preferred embodiment of the invention is shown in the cross-section of FIG. 1. The waveguide laser 2 comprises a ZBLAN fibre, with an inner core 4 doped with Pr³⁺ (typically between 100 and 10000 ppm), surrounded with a first cladding 6 doped with e.g. Tb³⁺-ions.

Tb³⁺-ions have a strong absorption at around 490 nm from the ⁷F₆-ground state to the ⁵D₄-exited state, but no absorption at the pump wavelength of the Pr-ion in the inner core (443 nm or between 800 and 900 nm). Thus, the embodiment of the invention using a Tb3+-doped cladding works both with linear conversion and a blue pump light source and a red or infrared pump light source, e.g. with a wavelength between 800 and 900 nm) and up-conversion.

The whole structure is surrounded with an outer or second cladding 8 that ensures the guiding of the laser radiation inside the fibre. Depending on the doping levels of Pr- and Tb-ions in the core 4 and first cladding 6, the refractive indices of core 4 and first cladding 6 can be varied to large extend.

The principle described above can easily also be applied to planar waveguide lasers. A planar waveguide laser is schematically drawn in FIG. 2. In this case a layered waveguide 10 is used with a very similar structure as described for the fibre-laser according to FIG. 1. The layers forming the second cladding 8, the first cladding 6 and the core 4 are deposited onto a substrate 12 forming a carrier for the layers.

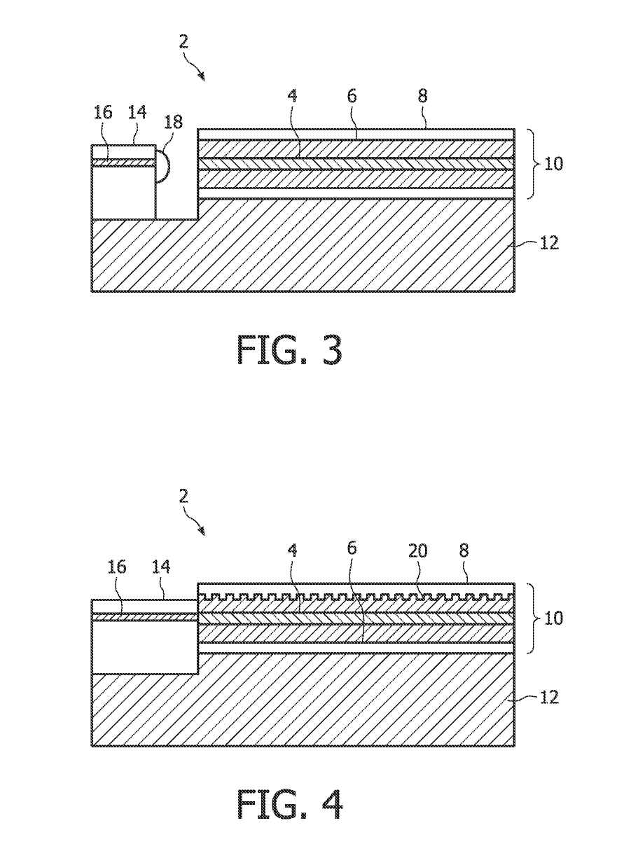

The sketched example shows the case of direct proximity coupling between the active layer 16 of a pump laser diode 14 and the waveguide layers 4, 6, 8. The additional advantage of the first cladding layer 6 is the relatively large cross section of the first cladding-waveguide, which enables to collect most of the radiation of the laser diode and therefore reduces coupling losses. With such an enlarged cross-section, it is also possible to place the diode at some distance from the waveguide 10 and still collect most of the (strongly divergent) pump radiation in the numerical aperture of the waveguide. Another possibility for a suitable setup is shown in FIG. 3. According to this embodiment, a simple lens 18 is placed in-between the pump laser diode 14 and the waveguide 10 with only low requirements on the position accuracy, as pump light coupled into the first cladding 6 also penetrates the core 4 due to the beam divergence of the focused pump light.

It is clear that Tb³⁺ is not the only ion, which can be used for the purpose of this invention. Other suitable ions and ion-host combinations can be found for the first cladding 6 in the technical literature, that match the requirements for absorption and transmission properties of this cladding.

Another alternative to using an absorbing material for the first cladding is a photonic structuring, that couples out radiation at the cyan wavelength or more generally at an undesired wavelength, while the pump and the laser radiation are still guided inside the waveguide. This example is sketched in FIG. 4.

The set-up of this exemplary embodiment is similar to the embodiment of FIG. 2. Instead of or additional to the Tb³⁺-doping of cladding 6, a photonic structuring 20 is introduced into the interface to the second cladding 8.

The photonic structuring may be generated by photolithographic structuring using light of the wavelength for the exposure which is to be coupled out.

Generally, it is preferred to choose the refractive index of the core 4 to be higher than the refractive index of the first cladding 6 at the desired laser wavelength in order to confine the desired laser radiation in the core 4. Even if the refractive indices at the first and second wavelengths are similar and the laser light of the second wavelength is guided as well, losses in the cladding can nevertheless introduced to the light of the second wavelength as its evanescent wave extends into the cladding 6.

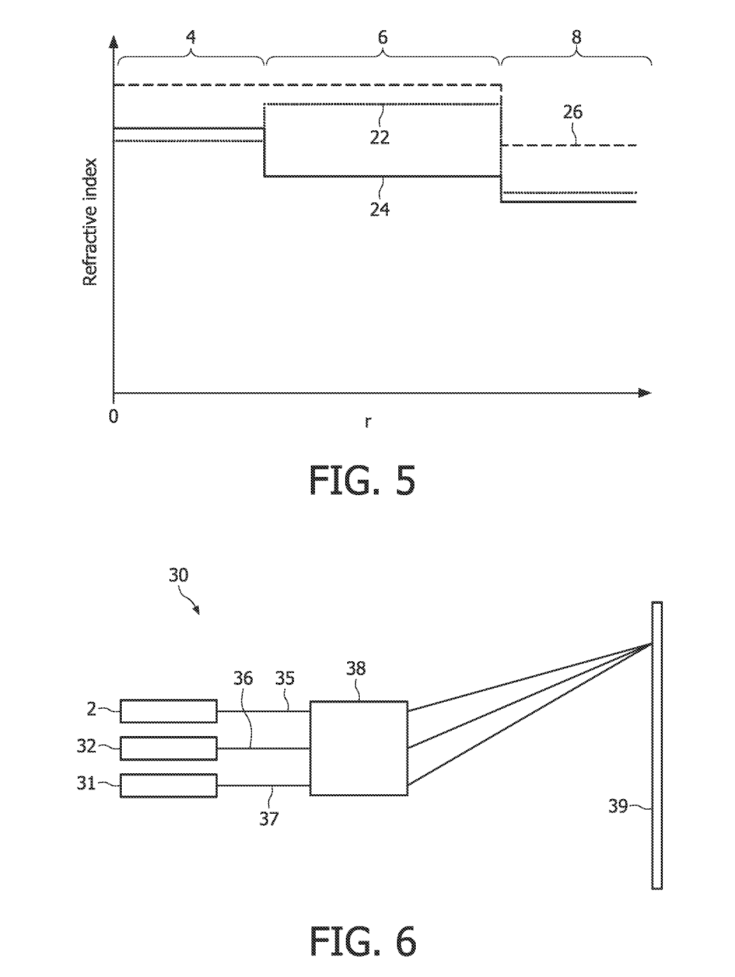

However, the dispersion of the cladding and the core may also be chosen so that the refractive index of the core at the first wavelength is higher than the refractive index of the cladding and is lower than the refractive index of the cladding at the second wavelength. An example is shown in the diagram of FIG. 5. The diagram shows two charts 22, 24 of the index of refraction along the radial direction r of a waveguide fibre as, e.g., shown in FIG. 1. Chart 24 reflects the course of the index of refraction at the first, desired wavelength along a radial direction and starting at r=0, i.e. at the centre of core 4. The course of the index of refraction for the second wavelength is shown as chart 22.

As can be seen from chart 24, the core 4 has a higher index of refraction than the first cladding 6 for the first wavelength so that the core guides the desired laser mode. In contrast thereto, as can be seen from chart 22, the refractive index at the second wavelength is higher within the cladding 6 compared to the core 4. This way, the undesired laser light of the second wavelength is not guided in the core 4 but coupled out into the cladding. This effect may be used to support the absorption of this laser light within the cladding or a deflection at a photonic structuring of the cladding 6. Moreover, this effect may be even sufficient for introducing losses to the undesired laser mode without the need of a photonic structuring or a cladding material which absorbs light of the second wavelength.

Further, as shown in the charts 22, 24, the refractive index within the second cladding may be lower than the refractive indices of the core and the cladding for both wavelengths.

A third chart 26 shows the course of the refractive index for the pump wavelength, for example 443 nm or a wavelength between 800 nm and 900 nm. According to the refinement of the invention illustrated by exemplary chart 26, the dispersions of the core and cladding materials are chosen so that the refractive indices at the pump wavelength are equal or at least substantially equal. Preferably, the difference of the refractive indices between core 4 and cladding 6 may be less than 0.05.

FIG. 6 shows a schematical setup of a laser projector 30 for projecting images or videos onto a screen 39. The laser projector comprises a waveguide laser 2 according to the invention along with two further lasers 31, 32. Each of the lasers 2, 31, 32 provides a different color component so that arbitrary colors can be generated by superposition and individually controlling the intensity of the laser beams 35, 36, 37 of the lasers 2, 31, 32, respectively. Thus, images are projected by controlling the intensity of the lasers 2, 31, 32 and simultaneously scanning the beams 35, 36, 37 across the screen 39. The beams 35, 36, 37 are deflected and scanned over the screen 39 by means of a modulator 38. For example, the modulator may comprise a DMD-chip (DMD=digital mirror device), a grating light valve or a galvanometer-scanner.

Although preferred embodiments of the present invention have been illustrated in the accompanying drawings and described in the foregoing description, it will be understood that the invention is not limited to the embodiments disclosed but is capable of numerous modifications without departing from the scope of the invention as set out in the following claims.

1. A waveguide laser (2) comprising a waveguide (1) with an elongated core (4) and at least one cladding (6) which at least partially surrounds said core (4),
said core (4) comprising a host material doped with a dopant providing at least two laser transitions at a first and a second wavelength, said host material being transparent at least at the first wavelength,
said cladding (6) being transparent to the laser light of the first wavelength and the pump light and absorbs or outcouples laser light of said second wavelength.

2. The waveguide laser (2) according to claim 1, in which said host material of said core (4) is doped with Praseodymium-ions, said host material being transparent at a wavelength of about 521±5 nm, and
said cladding (6) absorbing or outcoupling light having a wavelength of about 490±5 nm.

3. The waveguide laser according to claim 1, in which said cladding (6) guides said light of said pump source.

4. The waveguide laser according to claim 1, further comprising a second cladding (8) at least partially surrounding said first cladding (6).

5. The waveguide laser according to claim 1, in which said cladding (6) comprises a host material doped with Terbium-ions.

6. The waveguide laser according to claim 1, in which said cladding (6) comprises a photonic structuring (20) so that light of said first wavelength is guided within the cladding (6) and light of said second wavelength is coupled out.

7. The waveguide laser according to claim 1, in which said host material of said core (4) is ZBLAN-glass.

8. The waveguide laser according to claim 1, in which said host material of said core (4) has a phonon energy below 750 cm⁻¹ and a band gap of more than 6.5 eV

9. The waveguide laser according to claim 1, in which the concentration of said dopant providing at least two laser transitions at a first and a second wavelength in said core (4) is within a range of between 100 and 10000 ppm.

10. The waveguide laser according to claim 1, in which the core and cladding materials are chosen so that the refractive index of said core (4) at the first wavelength is higher than the refractive index of said cladding (6) and is lower than the refractive index of the cladding (6) at said second wavelength.

11. The waveguide laser according to claim 1, in which said core (4) is a fiber circumferentially surrounded by said cladding.

12. The waveguide laser according to claim 1, wherein said waveguide (10) is a planar waveguide arranged on a substrate (12).

13. The waveguide laser according to claim 1, further comprising a pump light source (14) coupled to one of the end faces of said waveguide (10).

14. The waveguide laser according to claim 9, in which the pump light source (14) is coupled at least partly to the end face of said cladding.

15. A laser projector (30) comprising a waveguide laser (2) according to claim 1.
